(19) United States
(12) Patent Application Publication
(10) Pub. No.: US 2007/0207632 A1
(43) Pub. Date: Sep. 6, 2007

(54) Midplane with offset connectors

(75) Inventor: Steven E. Minich, York, PA (US)

Correspondence Address: WOODCOCK WASHBURN, LLP, CIRA CENTRE, 12TH FLOOR, 2929 ARCH STREET, PHILADELPHIA, PA, 19104-2891, US

(73) Assignee: FCI Americas Technology, Inc., Reno, NV (US)

(21) Appl. No.: 11/367,183

(22) Filed: Mar. 3, 2006

(51) Int. Cl. H05K 1/00

(52) U.S. Cl. 439/65

(57) ABSTRACT

A first connector on a first side of a midplane circuit board may be offset from a second connector on a second side of the midplane circuit board. The first and second connectors may be substantially identical connectors, each with straight mounting contacts, to create an electrical interconnection therebetween without using a common signal via. Each side of the midplane may have the same footprint. Accordingly, substantially identical connectors may be used on both sides of the midplane circuit board.

### FIELD OF THE INVENTION

Generally, the invention relates to midplane connector systems. More particularly, the invention relates to midplane connector systems having midplane footprints that provide for offsetting connectors on opposite sides of a midplane circuit board.

### BACKGROUND OF THE INVENTION

An electronic system, such as a server, for example, may include components mounted on printed circuit boards, such as daughtercards, backplane boards, motherboards, midplane boards, and the like, that are interconnected to transfer power and data signals throughout the system. A typical midplane connector assembly may include electrical connectors disposed on opposite sides of a midplane circuit board, such that the electrical connectors are in electrical communication with each other. The electrical connectors may in turn be connected to a motherboard, daughtercard, backplane, and the like.

In some connector systems, there is a need to electrically connect an electronic component (e.g., daughtercard, etc.) positioned on one side or surface of a midplane circuit board to a corresponding electronic component (e.g., daughtercard, etc.) positioned on an opposite side or surface of the midplane. In the approach disclosed in U.S. Pat. No. 6,608,762, for example, pins from two contact modules extend into matching holes (i.e., the same through-hole or via) in a midplane. One set of pins extends into the holes from one side of the midplane, and the other set of pins extends into the same set of holes from the other side of the midplane. In another approach, disclosed in U.S. Pat. No. 6,392,142, only one pin is inserted into each hole in the midplane. Each of the single pins extends beyond the first and second surfaces of the midplane, and the pins receive plastic headers.

Such a configuration of matching holes or using common holes in the printed circuit board to provide electrical communication between two connectors may have disadvantages,such as requiring a thicker midplane than otherwise necessary. As such, there is a need for alternative configurations to overcome such disadvantages.

### SUMMARY OF THE INVENTION

A first connector on a first side of a midplane circuit board may be offset in a first direction from a second connector on a second side of the midplane circuit board. The first and second connectors may be substantially identical connectors, each with straight mounting contacts, to create an electrical interconnection between the connectors without a need for a common signal via. Each side of the midplane may have the same footprint and, therefore, substantially identical connectors may be used on both sides of the midplane circuit board.

An electrical assembly may include a midplane circuit board and first and second connectors. The midplane circuit board may include a substrate having a first side and a second side opposite the first side. The first and second sides each may have first and second electrically conductive sections for electrical communication with a connector. The first and second electrically conductive sections of the first side of the midplane circuit board may be in electrical communication with the first and second electrically conductive sections of the second side of the midplane circuit board, respectively. The first connector may have a first and second electrical contact. The first connector may be disposed on the first side of the midplane circuit board, wherein the first and second electrical contacts of the first connector may be in electrical communication with the first and second electrically conductive sections of the first side of the midplane circuit board, respectively. The second connector may have a first and second electrical contact. The second connector may be disposed on the second side of the midplane circuit board, wherein the first and second electrical contacts of the second connector are in electrical communication with the first and second electrically conductive sections of the second side of the midplane circuit board, respectively. The first and second electrical contacts of the second connector may be aligned with the first and second electrical contacts of the second connector in a first direction and may be offset from the first and second electrical contacts of the second connector in a second direction.

The first and second directions may be substantially orthogonal to each other. The first and second connectors each may have electrical contacts aligned in a row. The rows of contacts may be aligned along the axis of the row and offset along the axis substantially orthogonal to the row. The first connector and second connector may include electrical contacts arranged in an array of rows and columns. The rows may be aligned while the columns may be offset. The offset may be approximately half of the distance between neighboring electrical contacts. The contacts may include solder balls or pins and the electrically conductive sections of the midplane circuit board may include solder pads or electrically conductive vias. With the offset, connector pins need not share a common via.

### BRIEF DESCRIPTION OF THE DRAWINGS

FIG. 1 is a side view of a pair of electrical connectors disposed on opposite sides of a midplane circuit board.

FIG. 2 is a top view of the electrical connectors and midplane circuit board of FIG. 1.

FIG. 3 is a cut-away side view of a midplane circuit board via arrangement.

FIG. 4 is a cut-away side view of another midplane circuit board via arrangement.

FIG. 5 is a perspective view of a midplane via arrangement.

FIG. 6 is a side view of a pair of electrical connectors disposed on opposite sides of a midplane circuit board.

FIG. 7 is a top view of the electrical connectors and midplane circuit board of FIG. 6.

FIG. 8 is a cut-away side view of a midplane circuit board arrangement.

FIG. 9 is a perspective view of a midplane arrangement.

### DETAILED DESCRIPTION OF ILLUSTRATIVE EMBODIMENTS

FIG. 1 is a side view of a pair of electrical connectors 10 disposed on opposite sides of a midplane circuit board 30. The connectors 10 may be substantially identical, as shown, or may be different style connectors. The connectors 10 may be oriented similarly to each other, substantially orthogonally to each other, opposite each other, as shown, or may have other orientations with respect to each other. Connectors 10 may be right-angle connectors, mezzanine-style connectors, or the like.

Connector 10 may include a housing 12 for mechanically securing electrically conductive contacts 15 (described in more detail below). Housing 12 may be constructed of dielectric material, such as plastic, for example. Housing 12 may mechanically secure and retain electrically conductive contacts 15 in a desired position and electrically insulate between the electrically conductive contacts 15 with a dielectric material, such as air or plastic, or combinations thereof. Connector 10 may also include a plurality of insert molded lead frame assemblies (IMLAs), not shown. Each IMLA may mechanically secure electrically conductive contacts 15 that extend through a dielectric material, such as a plastic, for example.

Housing 12 may form a square envelope when viewed from a mating end of the connector 10 for receiving or mating with a corresponding connector, card, etc. Housing 12, however, may form a rectangular, or other shaped envelope. Housing 12 may define an area 17 for receiving a mating connector, a mating card, or the like (not shown). Area 17 may be formed for male-female type of connections or other types of connections.

Housing 12 may also include one or more elongated posts 20 which may serve as guide posts and pin protectors. Housing 12 may also define one or more recesses (not shown) for receiving respective elongated posts of a mating connector. The elongated posts 20 may extend towards the mating connector, as shown. The posts 20 may extend beyond the terminal ends of the contacts 15 and, consequently, protect the contacts from bending or other such damage during shipping, handling and mating. Further, to minimize the incidence of bending during insertion, the posts 20 and recesses may cooperate to guide the mating connector into mating engagement with connector 10 (or midplane circuit board 30) in such a way as to guide the contacts into an appropriate position. The elongated posts 20 may be made of an electrically insulating material, such as plastic, for example. The elongated posts 20 may also be keyed so that improper mating is avoided.

Electrically conductive contacts 15 have a first end 16 for mating with a midplane circuit board 30 and a second end 18 for mating with a mating connector. First end 16 typically extends from housing 12 towards midplane circuit board 30 more than one-half of the thickness of midplane circuit board 30, but can also extend other amounts. The first ends 16 may include terminal ends for engagement with a circuit board, such as a midplane 30. The first ends 16 may comprise compliant terminal ends, solder balls, contact pins, any surface-mount or through-mount terminal ends, and the like. Second end 18 typically extends from housing 12 away from midplane circuit board 30 and may be formed in a variety of ways, such as, for example, a male contact pin, a female contact pin, and the like.

Contacts 15 may be arranged in various ways, such as, for example, a row of contacts, an array of contacts 15 formed into rows and columns, and the like. The rows and columns may be formed using aligned IMLAs, where the IMLAs may be arranged as columns or rows. Also, though the connectors 10 are depicted with a certain number of electrically conductive contacts 15, it should be understood that any desired number of contacts 15 may be included.

Connector 10 may or may not include internal shielding (not shown), that is, material such as metallic shield plates, for example, between adjacent contact arrays, rows, columns, and the like.

Midplane circuit board 30 may be constructed of a substrate 36 and may include one or more differential signaling paths, one or more single-ended signaling paths, or a combination of differential signaling paths and single-ended signaling paths. Midplane circuit board 30 may also include one or more ground paths, which may be electrically connected to each other by traces and/or ground planes. A signaling path and a ground path may include an electrically conductive trace that is in electrical communication with an electrically conductive pad or with an electrically conductive via.

The conductive pads or electrically conductive vias may be in electrical communication with the first ends 16 of contacts 15. The first ends 16 of contacts 15 are typically electrically coupled to the conductive pads/vias (e.g., by soldering, BGA, press-fitting, or other techniques well-known in the art).

Though FIG. 1 illustrates a connector 10 having protruding contacts 15 that are received in vias of midplane circuit board 30. The respective contacts 15 of the pair of connectors 10 are offset by a distance “D” when viewed from the side of connector 10, such that the contacts are staggered in one direction. The distance “D” may be half the distance between neighboring contacts 15 on connector 10, as shown, or may be other distances.

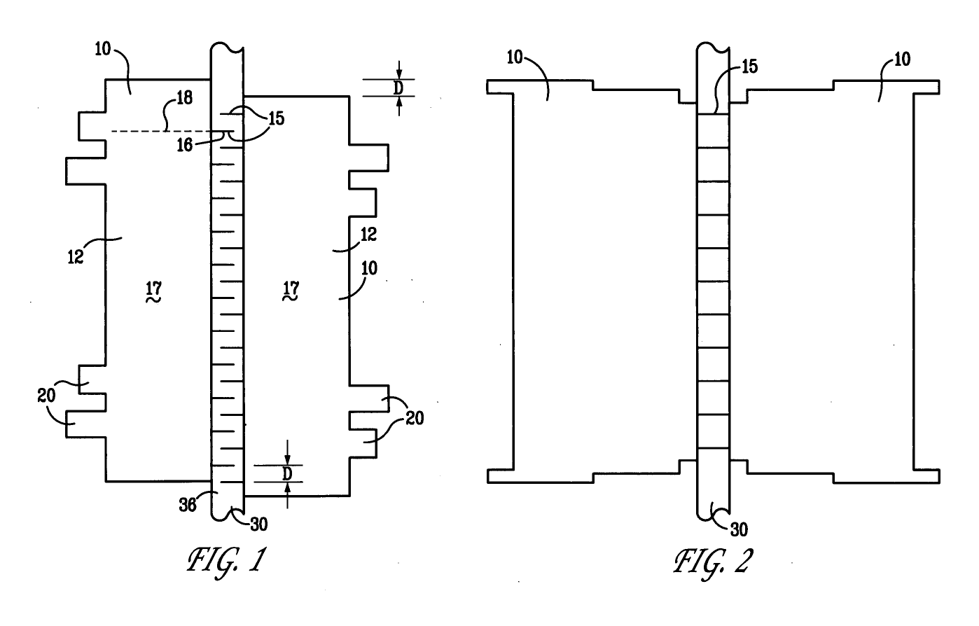

FIG. 2 shows a top view of the pair of electrical connectors 10 and midplane circuit board 30 of FIG. 1. As can be seen, from this top view, the respective contacts 15 of the pair of connectors 10 may be aligned in at least one direction (i.e., top-bottom as shown in FIG. 2).

FIG. 3 is a cut-away side view of a midplane circuit board 30 having electrically conductive blind vias 33 for receiving electrically conductive contacts 15. Midplane circuit board 30 may have a first side 31 and an opposing second side 32. Vias 33 are formed by each side 31, 32 of the midplane circuit board 30. As can be seen, each via 33 may have a corresponding via 33 located on the opposing side of midplane circuit board 30 that is electrical communication with that via 33. Corresponding vias 33 may be in electrical communication through a conductive trace 35 of midplane circuit board 30. In this manner, corresponding contacts 15 of the pair of connectors 10 may be in electrical communication when the connectors 10 are disposed on midplane circuit board 30. The conductive trace 35 may be located within midplane circuit board 30, as shown, on a face of midplane circuit board 30, combinations thereof, and the like.

As can be seen, the corresponding electrically conductive vias 33 (and the corresponding contacts 15 of the pair of connectors 10) are offset by a distance “D” when viewed from the side of midplane 30, such that the vias 33 are staggered in one direction and coincident in another direction. The distance “D” may be half the distance between neighboring vias 33 on one side of midplane circuit board 30, as shown, or may be other distances. In this manner, corresponding contacts 15 of the pair of connectors 10 may be in electrical communication when the connectors 10 are disposed on midplane circuit board 30 without having first ends 16 of contacts 15 sharing a common via 33.

As shown in FIG. 3, the electrically conductive vias 33 extend only partially through midplane circuit board 30 from the face of the first side 31 to some distance into the midplane circuit board 30. For example, the vias 33 may extend substantially halfway into midplane circuit board 30, or may extend other distances into midplane circuit board 30. The electrically conductive vias 33 may extend completely through the midplane circuit board 30 from the face of the first side 31 to the face of the second side 32, as shown in FIG. 4.

As shown in FIG. 4, signal vias 33 that extend completely through midplane circuit board 30 may have an “unused” end portion on the side of the midplane that does not receive a contact 15. Such unused end portions are hereinafter referred to as “stubs.” Such stubs may be removed with known techniques and may improve the electrical performance of the midplane circuit board 30.

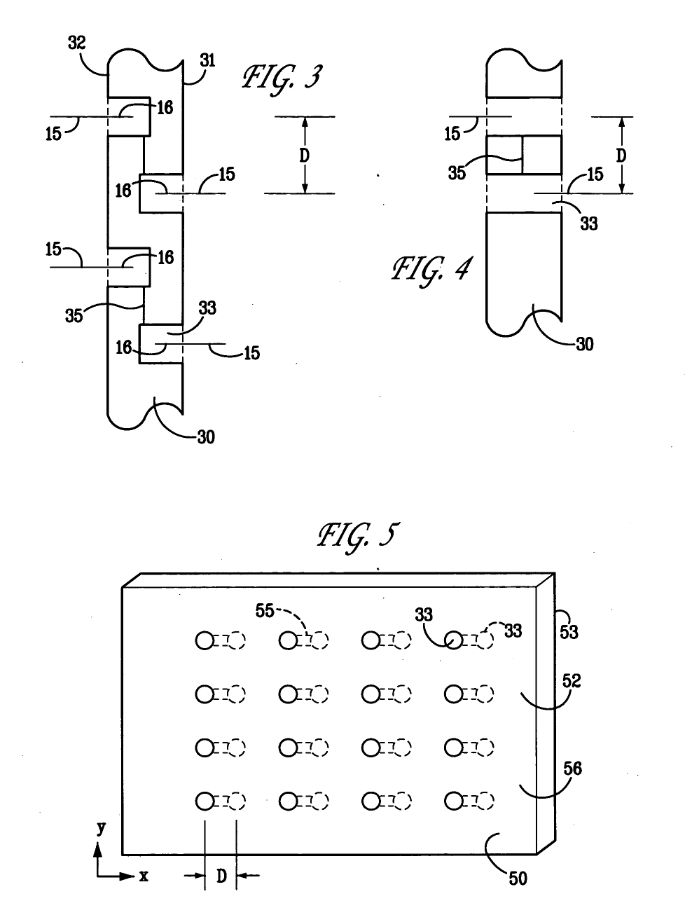

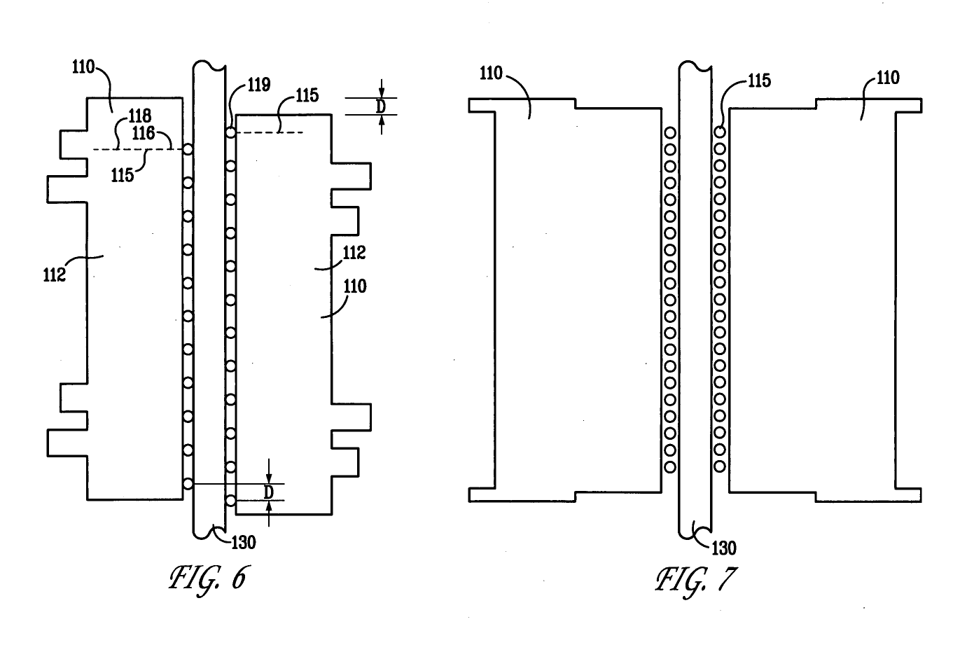

FIG. 5 is a perspective view of a midplane circuit board 50 having electrically conductive vias 33 arranged into an array of rows (x-direction) and columns (y-direction). Midplane circuit board 50 may comprise a substrate 56 having a front side 52 and an opposing back side 53. Each side (i.e., front side 52 and back side 53) of midplane circuit board 50 may have the same “footprint” for mating with a corresponding connector. Thus, identical connectors may be used on both sides of midplane circuit board 50. For example, as shown, front side 52 may define electrically conductive vias 33 arranged into an array of four rows and four columns for mating with an electrical connector. As shown, back side 53 may define electrically conductive vias 33 (shown with dashed lines) arranged into an array of four rows and four columns for mating with another electrical connector. While arrays of four rows and four columns are shown, there may be any number of rows and columns.

Corresponding electrically conductive vias 33 may be in electrical communication through a conductive trace 55. In this manner, corresponding contacts of a pair of connectors may be in electrical communication when the connectors are disposed on midplane circuit board 50. The conductive trace 55 may be located within midplane circuit board 50, as shown with dotted lines, on a face of midplane circuit board 50, combinations thereof, and the like.

The vias 33 defined by back side 53 may be offset by a distance “D” in the x direction from the corresponding vias 33 defined by front side 52. The distance “D” may be half the distance between neighboring vias 33 on one side of midplane circuit board 50, for example.

FIG. 6 is a side view of a pair of electrical connectors 110 disposed on opposite sides of a midplane circuit board 130. The connectors 110 may be substantially identical, as shown, or may be different style connectors. The connectors 110 may be oriented similarly to connectors 10 as described in connection with FIG. 1. Connectors 110 may be right-angle connectors, mezzanine-style connectors, or the like.

Connector 110 may include a housing 112 for mechanically securing electrically conductive contacts 115 similarly as described in connection with housing 12 of FIG. 1. Connector 110 may also include a plurality of insert molded lead frame assemblies (IMLAs), not shown. Each IMLA may mechanically secure electrically conductive contacts 115 that extend through a dielectric material, such as a plastic, for example. Electrically conductive contacts 115 may also include solder balls 119, as shown, for soldering contacts 115 to midplane circuit board 130.

Electrically conductive contacts 115 may have a first end 116 for mating with a midplane circuit board 130 and a second end 118 for mating with a mating connector. First end 116 typically extends from housing 112 towards midplane circuit board 130 about one-half of the thickness of midplane circuit board 30, but can extend other amounts. The first ends 116 may include terminal ends for engagement with a circuit board, such as a midplane 130. The first ends 116 may comprise compliant terminal ends, solder balls, contact pins, any surface-mount or through-mount terminal ends, and the like. Second end 118 typically extends from housing 112 away from midplane circuit board 130 and may be formed in a variety of ways, such as, for example, a male contact pin, a female contact pin, and the like.

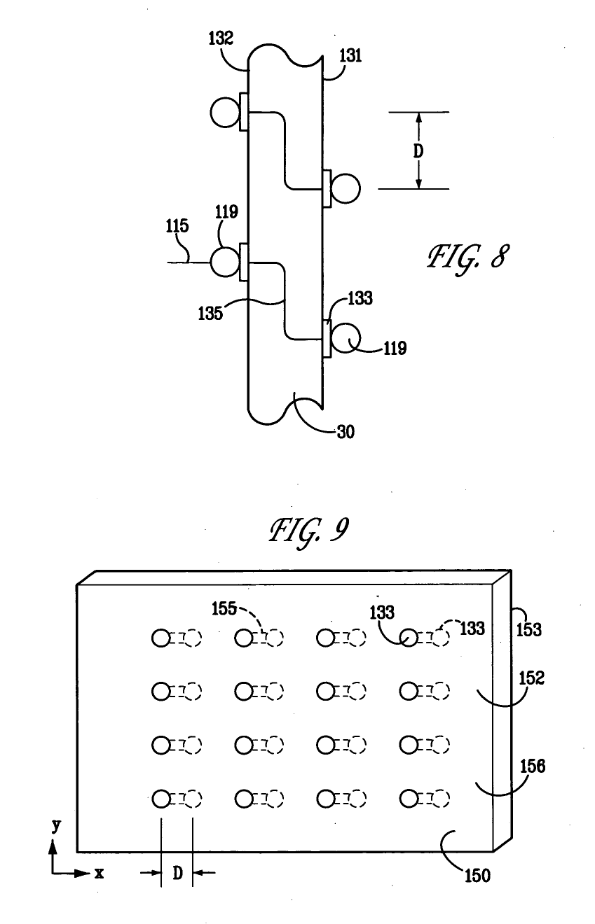

Midplane circuit board 130 may be constructed of a substrate 136 and may include one or more signaling paths and ground paths similarly as described in connection with midplane circuit board 30 of FIG. 1, having electrically conductive members, such as pads 133 (see FIGS. 8 and 9). The conductive pads may be in electrical communication with the first ends 116 of contacts 115. The first ends 116 of contacts 115 are typically electrically coupled to the conductive pads (e.g., by soldering). As shown, the first ends of contacts 115 may be coupled via solder balls 119 to the conductive pads of midplane circuit board 130.

As can be seen in FIG. 6, the respective contacts 115 of the pair of connectors 110 are offset by a distance “D” when viewed from the side of connector 110, such that the contacts are staggered in one direction. The distance “D” may be half the distance between neighboring contacts 115 on one side of connector 110, as shown, or may be other distances.

FIG. 7 shows a top view of the pair of electrical connectors 110 and midplane circuit board 130 of FIG. 6. As can be seen, from this top view, the respective contacts 115 of the pair of connectors 110 may be aligned in at least one direction (i.e., top-bottom as shown in FIG. 7).

FIG. 8 is a cut-away side view of a midplane circuit board 130 having electrically conductive pads 133 for electrical communication with electrically conductive contacts 115. Midplane circuit board 130 may have a first side 131 and an opposing second side 132. Electrically conductive pads 133 may be formed on each side 131, 132 of midplane circuit board 130. As can be seen, each pad 133 may have a corresponding pad 133 located on the opposing side of midplane circuit board 130 that is electrical communication with that pad 133. Corresponding pads 133 may be in electrical communication through a conductive trace 135 of midplane circuit board 130. In this manner, corresponding contacts 115 of the pair of connectors 110 may be in electrical communication when the connectors 110 are disposed on midplane circuit board 130 (e.g., via soldering of solder ball 119). The conductive trace 135 may be located within midplane circuit board 130, as shown, on a face of midplane circuit board 130, combinations thereof, and the like.

As can be seen, the corresponding electrically conductive pads 33 (and the corresponding contacts 115 of the pair of connectors 110) are offset by a distance “D” when viewed from the side of midplane 130, such that the pads 133 are staggered in one direction and coincident in another direction. The distance “D” may be half the distance between neighboring pads 133 on one side of midplane circuit board 130, as shown, or may be other distances.

FIG. 9 is a perspective view of a midplane circuit board 150 having electrically conductive pads 133 arranged into an array of rows (x direction) and columns (y direction). Midplane circuit board 150 may comprise a substrate 156 having a front side 152 and an opposing back side 153. As shown, front side 152 may include electrically conductive pads 133 arranged into an array of four rows and four columns for mating with an electrical connector. As shown, back side 153 may include electrically conductive pads 133 (shown with dashed lines) arranged into an array of four rows and four columns for mating with another electrical connector. While an array of four rows and four columns is shown, there may be any number of rows and columns.

Corresponding electrically conductive pads 133 may be in electrical communication through a conductive trace 155 of midplane circuit board 150. In this manner, corresponding contacts 115 of a pair of connectors may be in electrical communication when the connectors are disposed on midplane circuit board 150. The conductive trace 155 may be located within midplane circuit board 150, as shown with dotted lines, on a face of midplane circuit board 150, combinations thereof, and the like.

As can be seen, the pads 133 of back side 153 may be offset in the x direction from the corresponding pads 133 of front side 152, by a distance “D.” The distance “D” may be half the distance between neighboring pads 133 on one side of midplane circuit board 150, or may be other distances.

As can be seen, each side (i.e., front side 152 and back side 153) of midplane circuit board 150 may have the same “footprint” for mating with a corresponding connector. Thus, identical connectors may be used on both sides of midplane circuit board 150.

Thus, an electrical assembly is provided that allows for connectors (possibly identical connectors) to be used on opposite sides of a circuit board and be offset in one direction. In this manner, sharing a common electrically conductive via may be avoided. Further, real estate required for board thicknesses may be reduced.

What is claimed:

1. An electrical circuit board, comprising:
a substrate defining a first side and a second side opposite the first side, the first side having a first electrically conductive member for receiving a first electrical contact contained in a first electrical connector, the second side having a second electrically conductive member for receiving a second electrical contact contained in a second electrical connector,
wherein (i) the first member is in electrical communication with the second member, (ii) the first member is aligned with the second member along a first direction, and (iii) the first member is offset from the second member in the first direction.

2. The electrical circuit board of claim 1, wherein each of the first and second electrically conductive members are electrically conductive vias.

3. The electrical circuit board of claim 1, wherein each of the first and second electrically conductive members are electrically conductive pads.

4. The electrical circuit board of claim 1, further comprising:
a first trace that electrically connects the first and second vias.

5. The electrical circuit board of claim 4, wherein the first trace is disposed in an interior portion of the substrate.

6. The electrical circuit board of claim 1, wherein the first via extends only partially into the substrate from the first side thereof.

7. The electrical circuit board of claim 6, wherein the second via extends only partially into the substrate from the second side thereof.

8. The electrical circuit board of claim 1, wherein (i) the first side of the substrate has a third electrically conductive via for receiving a third electrical contact contained in the first electrical connector, (ii) the second side of the substrate has a fourth electrically conductive via for receiving a fourth electrical contact contained in the second electrical connector, and (iii) the third via is in electrical communication with the fourth via.

9. The electrical circuit board of claim 8, further comprising:
a first trace disposed in an interior portion of the substrate that electrically connects the first and second vias to one another, and a second trace disposed in the interior portion of the substrate that electrically connects the third and fourth vias to one another.

10. The electrical circuit board of claim 9, wherein the third via is aligned with the first via along a second direction that is orthogonal to the first direction, and the fourth via is aligned with the second via along the second direction.

11. An electrical circuit board, comprising:
a substrate defining a first side and a second side opposite the first side,
a first linear array of electrically conductive vias, each of which at least partially extends into the substrate from the first side thereof;
a second linear array of electrically conductive vias, each of which at least partially extends into the substrate from the second side thereof;
wherein (i) each of the vias in the first linear array is in electrical communication with a respective one of the vias in the second linear array, (ii) the first linear array is aligned with the second linear array along a first direction, and (iii) the first linear array is offset from the second linear array in a second direction.

12. The electrical circuit board of claim 11, further comprising:
a plurality of electrically conductive traces disposed in an interior portion of the substrate, wherein each of the plurality of traces electrically connects a respective one of the vias in the first linear array to the respective one of the vias in the second linear array.

13. The electrical circuit board of claim 11, wherein the first and second directions are orthogonal to one another.

14. An electrical connector assembly, comprising:
a midplane circuit board comprising a substrate having a first side and a second side opposite the first side, the first and second side each having first and second electrically conductive sections for electrical communication with a connector, the first and second electrically conductive sections of the first side of the midplane circuit board are in electrical communication with the first and second electrically conductive sections of the second side of the midplane circuit board, respectively;
a first connector having a first and second electrical contact, the first connector disposed on the first side of the midplane circuit board wherein the first and second electrical contacts of the first connector are in electrical communication with the first and second electrically conductive sections of the first side of the midplane circuit board, respectively;
a second connector having a first and second electrical contact, the second connector disposed on the second side of the midplane circuit board wherein the first and second electrical contacts of the second connector are in electrical communication with the first and second electrically conductive sections of the second side of the midplane circuit board, respectively;
wherein the first and second electrical contacts of the second connector are aligned with the first and second electrical contacts of the second connector in a first direction and are offset from the first and second electrical contacts of the second connector in a second direction.

15. The electrical assembly of claim 14, wherein the first and second directions are substantially orthogonal to each other.

16. The electrical assembly of claim 14, wherein the first connector comprises a plurality of electrical contacts aligned in a row on the first connector, the second connector comprises a plurality of electrical contacts aligned in a row on the second connector, the row of electrical contacts of the first connector being aligned with the row of electrical contacts of the second connector along an axis of the row of electrical contacts of the second connector and being offset from the row of electrical contacts of the second connector along an axis substantially orthogonal to the row of electrical contacts of the second connector.

17. The electrical assembly of claim 14, wherein the first connector comprises a plurality of electrical contacts arranged in a first array of rows and columns, the second connector comprises a plurality of electrical contacts arranged in a second array of rows and columns, the rows of electrical contacts of the first connector being aligned with the rows of electrical contacts of the second connector and the columns of electrical contacts of the first connector being offset from the columns of electrical contacts of the second connector.

18. The electrical assembly of claim 17, wherein the columns of electrical contacts of the first connector are offset from the columns of electrical contacts of the second connector by a distance that is approximately half of the distance between neighboring electrical contacts in the column of electrical contacts of the first connector.

19. The electrical assembly of claim 14, wherein the first and second electrical contacts of the first connector comprise electrical contact pins, the first and second electrical contacts of the second connector comprise electrical contact pins, the first and second electrically conductive sections of the first side of the midplane circuit board comprise electrically conductive vias that receive the first and second electrical contact pins of the first connector, respectively, and the first and second electrically conductive sections of the second side of the midplane circuit board comprise electrically conductive vias that receive the first and second electrical contact pins of the second connector, respectively, such that electrical contact pins do not share a common electrically conductive via.

20. The electrical assembly of claim 14, wherein the first and second electrical contacts of the first connector comprise solder balls, the first and second electrical contacts of the second connector comprise solder balls, the first and second electrically conductive sections of the first side of the midplane circuit board comprise electrically conductive pads that correspond to the first and second solder balls of the first connector, respectively, and the first and second electrically conductive sections of the second side of the midplane circuit board comprise electrically conductive pads that correspond to the first and second solder balls of the second connector, respectively.
